(19) United States
(12) Patent Application Publication
(10) Pub. No.: US 2018/0090682 A1
(43) Pub. Date: Mar. 29, 2018

(54) Organic Light-Emitting Diode Display Device Based On An Inkjet Printing Technology And Manufacturing Method For The Same

(71) Applicant: Shenzhen China Star Optoelectronics Technology Co. , Ltd., Shenzhen, Guangdong (CN)

(72) Inventor: Longqiang SHI, Shenzhen, Guangdong (CN)

(73) Assignee: Shenzhen China Star Optoelectronics Technology Co. , Ltd., Shenzhen, Guangdong (CN)

(21) Appl. No.: 15/028,371

(22) PCT Filed: Mar. 23, 2016
(86) PCT No.: PCT/CN2016/077109

§ 371 Date: Apr. 8, 2016

(30) Foreign Application Priority Data
Mar. 3, 2016 (CN) 201610121824.3

(51) Int. Cl. H01L 51/00; B41J 2/01; H01L 27/32

(52) U.S. Cl. CPC H01L 51/0005; B41J 2/01; H01L 51/5012; H01L 27/3246; H01L 27/3283; H01L 51/0012

(57) ABSTRACT

An OLED display device based on inkjet printing technology and a manufacturing method are disclosed. The device includes: a glass substrate, and a metal layer, an anode layer, a bank layer, an organic light-emitting layer and a cathode layer sequentially disposed on the glass substrate; wherein, an area of the metal layer covering on the glass substrate is provided with three opening regions to reveal the glass substrate corresponding to the three opening regions; an area of the bank layer covering on the anode layer is provided with a fourth opening region to reveal the anode layer corresponding to the fourth opening region; the organic light-emitting layer is disposed inside the fourth opening region; wherein, a hydrophobic material layer is disposed on a surface of the bank layer in parallel with the glass substrate. Accordingly, OLED material can distribute evenly, and the OLED device can emit an even light.

### BACKGROUND OF THE INVENTION

### 1. Field of the Invention

The present application relates to a display technology field, and more particularly to an organic light-emitting diode display device based on the inkjet printing technology and manufacturing method for the same.

### 2. Description of Related Art

Along with the fast development of the inkjet printing technology, more and more companies use the inkjet printing technology to manufacture the Organic Light-Emitting Diode (OLED) and the organic light-emitting diode display device.

Wherein, in the conventional technology, a simple cross-sectional view of an OLED device based on the inkjet printing technology is shown as FIG. 1, and including a substrate 110, a metal electrode 120, an indium tin oxide (ITO) anode 130, a bank layer 140, an organic light-emitting layer 150, and a cathode 160.

The first key step of the inkjet printing technology is to treat the bank layer 140 as having a surface hydrophobicity, and the second key step of the inkjet printing technology is to spray the OLED ink to a groove formed in the bank layer 140. Because most of the OLED ink is hydrophilic, when the OLED ink is sprayed on the bank layer, because of a poor contact force between the hydrophilicity and the hydrophobicity, the OLED ink will fall into the groove formed in the bank layer 140. However, because a contact angle of the ink and the groove will directly affect the uniformity of the ink inside the groove, when spraying the OLED ink on the bank layer and the contact angle of the OLED ink and the groove is improper (for example, the contact angle >90°), a contact between a base of the ITO anode and the OLED material is poor, a gap is existed between the groove and the OLED material, a distribution of the OLED material is thick at a middle portion and thin at two terminals such that the uniformity is poor and is not conducive to emit an even light.

### SUMMARY OF THE INVENTION

The present invention provides an organic light-emitting diode display device based on the inkjet printing technology and manufacturing method for the same, which can evenly distribute the OLED material, and make the OLED device to emit an even light.

In order to solve the above technology problem, a technology solution adopted by the present invention is: providing an organic light-emitting diode (OLED) display device based on an inkjet printing technology comprising: a glass substrate; a metal layer, an anode layer, a bank layer, an organic light-emitting layer and a cathode layer sequentially disposed on the glass substrate; wherein, an area of the metal layer covering on the glass substrate is provided with three opening regions to reveal the glass substrate which is corresponding to the three opening regions; an area of the bank layer covering on the anode layer is provided with a fourth opening region to reveal the anode layer which is corresponding to the fourth opening region; the organic light-emitting layer is disposed inside the fourth opening region; wherein, a hydrophobic material layer is disposed on a surface of the bank layer which is in parallel with the glass substrate, and the hydrophobic material layer includes fluorine ion or chloride ion; the bank layer is a negative photoresist.

Wherein, a material of the anode is indium tin oxide.

Wherein, a shape formed in the fourth opening region is an inverted trapezoidal shape.

In order to solve the above technology problem, another technology solution adopted by the present invention is: providing an organic light-emitting diode (OLED) display device based on an inkjet printing technology comprising: a glass substrate; a metal layer, an anode layer, a bank layer, an organic light-emitting layer and a cathode layer sequentially disposed on the glass substrate; wherein, an area of the metal layer covering on the glass substrate is provided with three opening regions to reveal the glass substrate which is corresponding to the three opening regions; an area of the bank layer covering on the anode layer is provided with a fourth opening region to reveal the anode layer which is corresponding to the fourth opening region; the organic light-emitting layer is disposed inside the fourth opening region; wherein, a hydrophobic material layer is disposed on a surface of the bank layer which is in parallel with the glass substrate.

Wherein, the hydrophobic material layer includes fluorine ion or chloride ion.

Wherein, the bank layer is a negative photoresist.

Wherein, a shape formed in the fourth opening region is an inverted trapezoidal shape.

In order to solve the above technology problem, another technology solution adopted by the present invention is: providing a manufacturing method for an organic light-emitting diode (OLED) display device based on an inkjet printing technology comprising steps of: sequentially forming a metal layer, an anode layer and a bank layer on a substrate; wherein, three opening regions are provided at an area of the metal layer covering on the substrate to reveal the substrate which is corresponding to the three opening regions; providing a fourth opening region at an area of the bank layer covering on the anode layer to reveal a portion of the anode layer which is corresponding to the fourth opening region; forming a photoresist layer on the portion of the anode which is corresponding to the fourth opening region and a surface of the bank layer; wherein, a photoresist property of the photoresist layer and a photoresist property of bank layer are different; exposing the photoresist layer to reveal a surface of the bank layer which is in parallel with the substrate; forming a hydrophobic material layer on the surface of the bank layer which is in parallel with the substrate; and exposing and developing to remove the photoresist layer, using an inkjet printing technology to form an organic light-emitting layer in the fourth opening region, and forming a cathode layer on the organic light-emitting layer.

Wherein, the step of forming a hydrophobic material layer on the surface of the bank layer which is in parallel with the substrate is: performing a dry etching process to the surface of the bank layer in order to form the hydrophobic material layer on the surface of the bank layer.

Wherein, the hydrophobic material layer includes fluorine ion or chloride ion.

Wherein, the bank layer is a negative photoresist and the photoresist layer is a positive photoresist.

Wherein, the step of exposing the photoresist layer to reveal a surface of the bank layer which is in parallel with the substrate is exposing the photoresist layer within a preset time to reveal a surface of the bank layer which is in parallel with the substrate.

In the above solution, in the organic light-emitting diode display device based on the inkjet printing technology, the hydrophobic material layer is disposed on the surface of the bank layer which is in parallel with the substrate. The fourth opening region provided by the bank layer is not covered with the hydrophobic material layer such that all of the sprayed OLED ink can fall into the fourth opening region and the OLED ink can fully contact with the surface of the fourth opening region so as to evenly distribute the OLED ink in the fourth opening region in order to form an even organic light-emitting layer, and the organic light-emitting diode display device can emit an even light.

### BRIEF DESCRIPTION OF THE DRAWINGS

FIG. 1 is a schematic simple cross-sectional view of an OLED device based on an inkjet printing technology of the conventional art;

FIG. 2 is a schematic simple cross-sectional view of an OLED device based on an inkjet printing technology of the present invention;

FIG. 3 is a flowchart of a manufacturing method of an organic light-emitting diode display device based on an inkjet printing technology of an embodiment of the present invention; and

FIG. 4 to FIG. 10 are cross-sectional views of the organic light-emitting diode display device at different manufacturing processes of the manufacturing method of the organic light-emitting diode display device based on an inkjet printing technology of an embodiment of the present invention.

### DETAILED DESCRIPTION OF THE PREFERRED EMBODIMENT

The following description is for explanation, not for limiting to provide a specific detail such as specific system structure, port and technology to understand the present invention thoroughly.

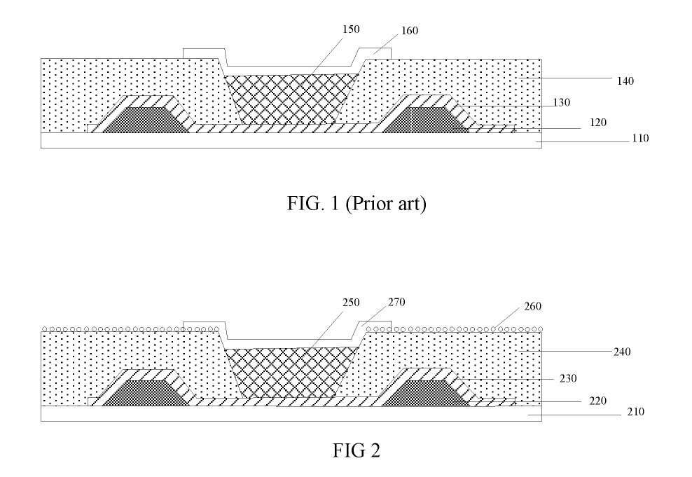

With reference to FIG. 2, and FIG. 2 is a schematic simple cross-sectional view of an OLED display device based on the inkjet printing technology of the conventional art. The organic light-emitting diode (OLED) display device includes a glass substrate 210, and a metal layer 220, an anode layer 230, a bank layer 240, a hydrophobic material layer 250, an organic light-emitting layer 260 and a cathode layer 270 sequentially disposed on the glass substrate 210.

Wherein, an area of the metal layer 220 covering on the glass substrate 210 is provided with three opening regions to reveal the glass substrate 210 which is corresponding to the three opening regions; an area of the bank layer 240 covering on the anode layer 230 is provided with a fourth opening region to reveal the anode layer 230 which is corresponding to the fourth opening region. The organic light-emitting layer 260 is disposed inside the fourth opening region; the hydrophobic material layer 250 is disposed on a surface of the bank layer 240 which is in parallel with the glass substrate 210, and a surface of the fourth opening region is not covered with the hydrophobic material layer 250.

The metal layer 220 is used to connect with the anode layer 230 to reduce an internal resistance. Furthermore, a material of the anode layer 230 can be an indium tin oxide (ITO) or other transparent conductive materials, the present invention is not limited.

A material of the bank layer 240 is a photoresist material. The fourth opening region provided by the bank layer 240 is used for utilizing the inkjet printing technology to spray the OLED ink to the fourth opening region in order to form an organic light-emitting layer 260.

Furthermore, the material of the bank layer 240 is a negative photoresist material. It can be understood that in another embodiment, the material of the bank layer 240 is a positive photoresist material, the present invention is not limited.

Furthermore, a shape formed in the fourth opening region is an inverted trapezoidal shape. An angle formed between a surface of the fourth opening region and a plane where the anode layer 230 is located is greater than 90 degrees such that when spraying the OLED ink, the OLED ink can fully contact with the surface of the fourth opening region in order to prevent a situation that the OLED ink cannot be sprayed on the surface of the fourth opening region.

The hydrophobic material 250 is used for forming a hydrophobic group with the material of the bank layer 240. Because the OLED ink is generally a hydrophilic material, when spraying the OLED ink to the fourth opening region of the bank layer 240, the hydrophobic material layer 250 covering the surface of the bank layer 240 which is in parallel with the glass substrate 210 make all of the sprayed OLED ink to fall into the fourth opening region and make the OLED ink to fully contact with the surface of the fourth opening region (the contact angle between the OLED ink and the surface of the fourth opening region is less than 90 degrees, to evenly distribute the OLED ink in order to form an even organic light-emitting layer 260.

Because the hydrophobic material layer 250 is disposed on the surface of the bank layer 240 which is in parallel with the glass substrate 210, and the surface of the fourth opening region is not covered with the hydrophobic material layer 250 such that the surface of the fourth opening region also being hydrophobic is avoided in order to avoid an uneven light emitting situation of the OLED display device caused by an uneven distribution of the OLED ink because of a poor contact of the sprayed OLED ink and the surface of the fourth opening region.

Furthermore, the hydrophobic material layer 250 includes fluoride ion or chlorine ion. However, the present invention is not limited, other hydrophobic ions can be used.

In the above solution, in the organic light-emitting diode display device based on the inkjet printing technology, the hydrophobic material layer is disposed on the surface of the bank layer which is in parallel with the substrate. The fourth opening region provided by the bank layer is not covered with the hydrophobic material layer such that all of the sprayed OLED ink can fall into the fourth opening region and the OLED ink can fully contact with the surface of the fourth opening region so as to evenly distribute the OLED ink in the fourth opening region in order to form an even organic light-emitting layer, and the organic light-emitting diode display device can emit an even light.

A shape formed in the fourth opening region is an inverted trapezoidal shape. An angle formed between a surface of the fourth opening region and a plane where the anode layer is located is greater than 90 degrees such that a situation that the OLED ink cannot be sprayed on the surface of the fourth opening region can be prevented.

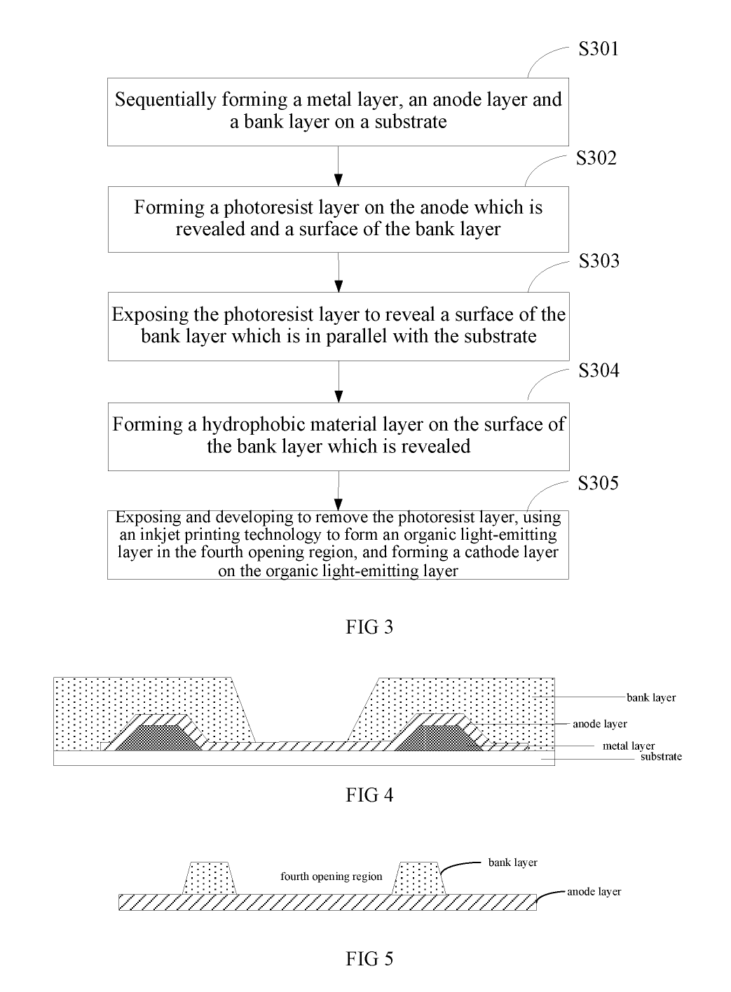

With reference to FIG. 3, and FIG. 3 is a flowchart of a manufacturing method for an organic light-emitting diode (OLED) display device based on an inkjet printing technology of an embodiment of the present invention. The manufacturing method for an organic light-emitting diode (OLED) display device based on an inkjet printing technology of the present embodiment comprises following steps:

S301: sequentially forming a metal layer, an anode layer and a bank layer on a substrate; wherein, three opening regions are provided at an area of the metal layer covering on the substrate to reveal the substrate which is corresponding to the three opening regions; providing a fourth opening region at an area of the bank layer covering on the anode layer to reveal the anode layer which is corresponding to the fourth opening region.

With reference to FIG. 4 to FIG. 10, and FIG. 4 to FIG. 10 are cross-sectional views of the organic light-emitting diode display device at different manufacturing processes of the manufacturing method for the organic light-emitting diode display device based on an inkjet printing technology of an embodiment of the present invention.

As shown in FIG. 4, sputtering a metal layer on a substrate and etching three opening regions at a preset location of the metal layer to reveal the substrate which is corresponding to the three opening regions; sputtering indium tin oxide on the metal layer and the substrate which is corresponding to the three opening regions and revealed in order to form an anode layer, coating a first photoresist material on the anode layer to form a bank layer, and providing a fourth opening region at a preset region to reveal a portion of the anode layer which is corresponding to the fourth opening region, as shown in FIG. 5.

Wherein, a shape formed in the fourth opening region is an inverted trapezoidal shape. An angle formed between a surface of the fourth opening region and a plane where the anode layer is located is greater than 90 degrees such that when spraying the OLED ink, the OLED ink can fully contact with the surface of the fourth opening region so as to prevent a situation that the OLED ink cannot be sprayed on the surface of the fourth opening region.

It can be understood that, in another embodiment, a material of the first photoresist material can be a positive photoresist material, or a negative photoresist material.

S302: forming a photoresist layer on the portion of the anode which is revealed and corresponding to the fourth opening region and a surface of the bank layer; wherein, a photoresist property of the photoresist layer and a photoresist property of bank layer are different.

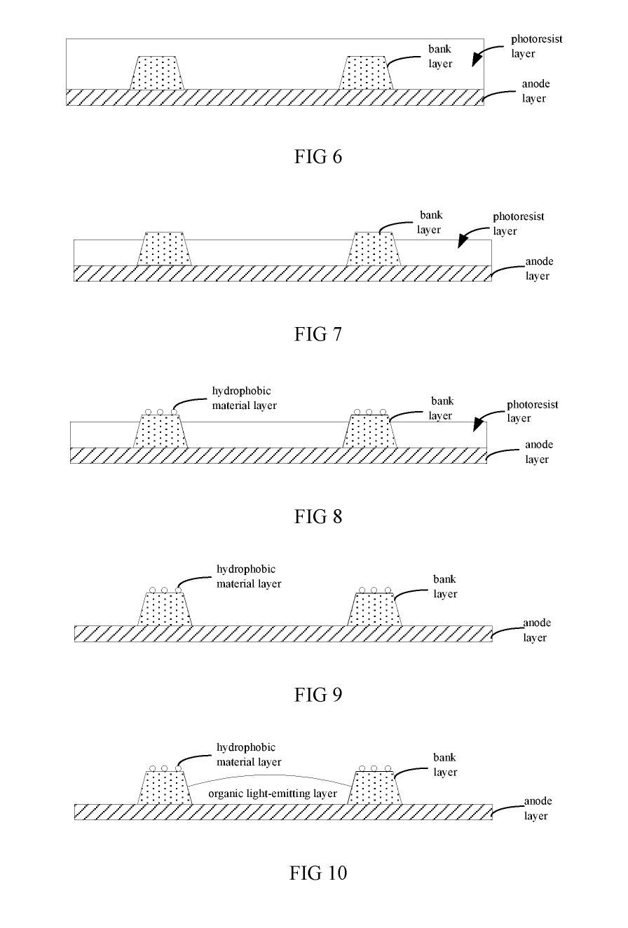

As shown in FIG. 6, coating a second photoresist material on the anode layer which is revealed and the bank layer to form the photoresist (PR) layer.

Wherein, the photoresist property of the photoresist layer and the photoresist property of bank layer are different. When the first photoresist material of the bank layer is a positive photoresist material, the second photoresist material of the photoresist (PR) layer is a negative photoresist material; when the first photoresist material of the bank layer is a negative photoresist material, the second photoresist material of the photoresist (PR) layer is a positive photoresist material. The specific photoresist materials can be selected according to the requirements of the photoresist properties, the specific photoresist materials are not limited.

Furthermore, in the present embodiment, the bank layer is a negative photoresist, and the photoresist layer is a positive photoresist.

S303: exposing the photoresist layer to reveal a surface of the bank layer which is in parallel with the substrate, and a surface of the fourth opening region is still covered with photoresist material of the photoresist layer, and a schematic drawing of the photoresist layer after exposing is as shown in FIG. 7.

Furthermore, the step S305 specifically is: exposing the photoresist layer within a present time to reveal a surface of the bank layer which is in parallel with the substrate.

For example, the photoresist material in the photoresist layer will react when encountering a light, controlling an exposure amount to the photoresist layer, and exposing and developing the photoresist layer within a preset time to reveal the surface of the bank layer which is in parallel with the substrate, and the surface of the fourth opening region is still covered with the photoresist material of the photoresist layer.

S304: forming a hydrophobic material layer on the surface of the bank layer which is in parallel with the substrate and revealed.

Etching the surface of the bank layer which is revealed in order to form a hydrophobic material layer. A schematic drawing of the hydrophobic material layer after formed is shown in FIG. 8.

Furthermore, the step S304 specifically is: performing a dry etching process to the surface of the bank layer in order to form the hydrophobic material layer on the surface of the bank layer which is revealed.

For example, through an etching gas to perform a dry etching process to the surface of the bank layer which is in parallel with the substrate, the surface of the bank layer which is revealed forms the hydrophobic material layer including hydrophobic group. The surface of the bank layer which is revealed including the hydrophobic group is used for when spraying the OLED to the fourth opening region, all of the OLED ink can be sprayed in the fourth opening region, and contacting well with the surface of the fourth opening region in order to form an even organic light-emitting layer in the fourth opening region. Accordingly, the surface of the fourth opening region also being hydrophobic is avoided in order to avoid an uneven light emitting situation of the OLED display device caused by an uneven distribution of the OLED ink because of a poor contact of the sprayed OLED ink and the surface of the fourth opening region.

Furthermore, the etching gas can be CF₄+O₂, Cl₂+O₂ or CCl₆+CL₂, however, the present embodiment is not limited.

When the etching gas is CF₄+O₂, the hydrophobic material layer includes fluoride ion (F⁺), and when the etching gas is Cl₂+O₂ or CCl₆+CL₂, the hydrophobic material layer includes chloride ion (Cl⁻).

S305: exposing and developing to remove the photoresist layer, using an inkjet printing technology to form an organic light-emitting layer in the fourth opening region, and forming a cathode layer on the organic light-emitting layer.

Exposing and developing to the photoresist layer to remove a remaining second photoresist material in the photoresist layer. A schematic drawing after removing the remaining second photoresist material in the photoresist layer is shown as FIG. 9.

After removing the remaining second photoresist material in the photoresist layer, utilizing an inkjet printing technology to spray the OLED ink in the fourth opening region in order to evenly distribute the OLED ink in the fourth opening region to form an organic light-emitting layer, as shown in FIG. 10.

After forming the organic light-emitting layer, forming a cathode on the organic light-emitting layer.

In the above solution, in the organic light-emitting diode display device based on the inkjet printing technology, the hydrophobic material layer is disposed on the surface of the bank layer which is in parallel with the substrate. The fourth opening region provided by the bank layer is not covered with the hydrophobic material layer such that all of the sprayed OLED ink can fall into the fourth opening region and the OLED ink can fully contact with the surface of the fourth opening region so as to evenly distribute the OLED ink in the fourth opening region in order to form an even organic light-emitting layer, and the organic light-emitting diode display device can emit an even light.

A shape formed in the fourth opening region is an inverted trapezoidal shape. An angle formed between a surface of the fourth opening region and a plane where the anode layer is located is greater than 90 degrees such that a situation that the OLED ink cannot be sprayed on the surface of the fourth opening region can be prevented.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. An organic light-emitting diode (OLED) display device based on an inkjet printing technology comprising:
a glass substrate;
a metal layer, an anode layer, a bank layer, an organic light-emitting layer and a cathode layer sequentially disposed on the glass substrate;
wherein, an area of the metal layer covering on the glass substrate is provided with three opening regions to reveal the glass substrate which is corresponding to the three opening regions; an area of the bank layer covering on the anode layer is provided with a fourth opening region to reveal the anode layer which is corresponding to the fourth opening region; the organic light-emitting layer is disposed inside the fourth opening region; wherein, a hydrophobic material layer is disposed on a surface of the bank layer which is in parallel with the glass substrate, and the hydrophobic material layer includes fluorine ion or chloride ion; the bank layer is a negative photoresist.

2. The device according to claim 1, wherein, a material of the anode layer is indium tin oxide.

3. The device according to claim 1, wherein, a shape formed in the fourth opening region is an inverted trapezoidal shape.

4. An organic light-emitting diode (OLED) display device based on an inkjet printing technology comprising:
a glass substrate;
a metal layer, an anode layer, a bank layer, an organic light-emitting layer and a cathode layer sequentially disposed on the glass substrate;
wherein, an area of the metal layer covering on the glass substrate is provided with three opening regions to reveal the glass substrate which is corresponding to the three opening regions; an area of the bank layer covering on the anode layer is provided with a fourth opening region to reveal the anode layer which is corresponding to the fourth opening region; the organic light-emitting layer is disposed inside the fourth opening region; wherein, a hydrophobic material layer is disposed on a surface of the bank layer which is in parallel with the glass substrate.

5. The device according to claim 4, wherein, the hydrophobic material layer includes fluorine ion or chloride ion.

6. The device according to claim 4, wherein, the bank layer is a negative photoresist.

7. The device according to claim 6, wherein, a material of the anode layer is indium tin oxide.

8. The device according to claim 6, wherein, a shape formed in the fourth opening region is an inverted trapezoidal shape.

9. A manufacturing method for an organic light-emitting diode (OLED) display device based on an inkjet printing technology comprising steps of:
sequentially forming a metal layer, an anode layer and a bank layer on a substrate; wherein, three opening regions are provided at an area of the metal layer covering on the substrate to reveal the substrate which is corresponding to the three opening regions; providing a fourth opening region at an area of the bank layer covering on the anode layer to reveal a portion of the anode layer which is corresponding to the fourth opening region;
forming a photoresist layer on the portion of the anode which is corresponding to the fourth opening region and a surface of the bank layer; wherein, a photoresist property of the photoresist layer and a photoresist property of bank layer are different;
exposing the photoresist layer to reveal a surface of the bank layer which is in parallel with the substrate;
forming a hydrophobic material layer on the surface of the bank layer which is in parallel with the substrate; and
exposing and developing to remove the photoresist layer, using an inkjet printing technology to form an organic light-emitting layer in the fourth opening region, and forming a cathode layer on the organic light-emitting layer.

10. The method according to claim 9, wherein, the step of forming a hydrophobic material layer on the surface of the bank layer which is in parallel with the substrate is: performing a dry etching process to the surface of the bank layer in order to form the hydrophobic material layer on the surface of the bank layer which is revealed.

11. The method according to claim 10, wherein, the hydrophobic material layer includes fluorine ion or chloride ion.

12. The method according to claim 9, wherein, the bank layer is a negative photoresist and the photoresist layer is a positive photoresist.

13. The method according to claim 9, wherein, the step of exposing the photoresist layer to reveal a surface of the bank layer which is in parallel with the substrate is exposing the photoresist layer within a preset time to reveal a surface of the bank layer which is in parallel with the substrate.
